(19) United States
(12) Patent Application Publication
(10) Pub. No.: US 2026/0331871 A1
(43) Pub. Date: Oct. 22, 2026

(54) LIGHT EMITTING DEVICE AND MANUFACTURING METHOD THEREOF

(71) Applicant: Taiwan-Asia Semiconductor Corporation, Hsinchu City (TW)

(72) Inventors: Kun-Li Lin, Hsinchu City (TW); Chuan-Wei Chen, Hsinchu City (TW); Yu-Tong Hsiao, Hsinchu City (TW)

(21) Appl. No.: 19/288,438

(22) Filed: Aug. 1, 2025

(30) Foreign Application Priority Data
Apr. 22, 2025 (TW) 114115234

(51) Int. Cl. H01S 5/183; H01S 5/024; H01S 5/042

(52) U.S. Cl. CPC H01S 5/18394; H01S 5/02469; H01S 5/04254

(57) ABSTRACT

A light-emitting device and a manufacturing method thereof are provided. The light-emitting device includes an epitaxial layer, a first electrode, a trench, a second electrode, and a heat dissipation metal. The epitaxial layer has a current confinement region and an active layer. The first electrode is disposed on the epitaxial layer and has an emission aperture. The trench is disposed on a side of the epitaxial layer opposite to the emission aperture. The second electrode covers a surface of the trench. The heat dissipation metal covers the trench. When a current flows through the first electrode and the current confinement region into the active layer, the active layer excites a light beam to pass through the current confinement region and the emission aperture to exit the epitaxial layer, and the heat generated by the active layer in the current confinement region is dissipated externally through the heat dissipation metal in the trench.

### CROSS-REFERENCES TO RELATED APPLICATIONS

This application claims the benefit of priority to Taiwanese Patent Application No. 114115234 filed on Apr. 22, 2025, which is hereby incorporated by reference in its entirety.

### BACKGROUND OF THE INVENTION

### Field of the Invention

This invention relates to a light-emitting device and a manufacturing method thereof, and in particular to a light-emitting device with a high thermal conductivity structure and a manufacturing method thereof.

### Descriptions of the Related Art

A Vertical Cavity Surface Emitting Laser (VCSEL) device confines current to a small region using an oxide layer, referred to as an Oxidation Aperture (OA), forming a high-density current to achieve a lower threshold current for achieving lasing.

Since the current is confined by the oxide layer to a small region within the light-emitting active layer, the heat dissipation model resembles a point heat source, with heat flow diffusion approximating a cosine function distribution, where power density is inversely proportional to the distance from the heat source. Due to the high local current density in the light-emitting active layer and the resulting temperature rise, the energy band gap becomes distorted, leading to a roll-over relationship between current and power, causing a decrease in power output efficiency at high currents and even failure to lase at high temperatures.

In conventional VCSEL devices, the back electrode serves as a flat heat dissipation structure, which is far from the light-emitting active layer generating the heat, making heat dissipation difficult. Moreover, unlike other devices, the heat dissipation model of conventional VCSEL devices is independent of device volume, so increasing the device size does not improve heat dissipation efficiency. Therefore, there is an urgent need to effectively enhance the heat dissipation efficiency of VCSEL devices to prevent burnout of the OA region due to poor heat dissipation.

### SUMMARY OF THE INVENTION

The objective of this invention is to provide a light-emitting device and a manufacturing method thereof, optimizing the thermal conduction structure of the light-emitting device proposed in Taiwan Patent No. I878998 (US2025/0047064A1), providing a three-dimensional heat dissipation pathway to overcome the limitations of the cosine function heat dissipation model of the conventional point heat source, shorten the heat dissipation path, and achieve improved heat dissipation efficiency and device reliability for VCSEL devices.

To achieve the above objective, this invention provides a light-emitting device comprising an epitaxial layer, a first electrode, a trench, a second electrode, and a heat dissipation metal. The epitaxial layer includes a current confinement region and an active layer. The first electrode is disposed on the epitaxial layer and has an emission aperture. The trench is disposed on a side of the epitaxial layer opposite to the emission aperture. The second electrode covers a surface of the trench. The heat dissipation metal covers the trench. When a current flows through the first electrode and the current confinement region into the active layer, the active layer excites a light beam to pass through the current confinement region and the emission aperture to exit the epitaxial layer, and the heat generated by the active layer in the current confinement region is dissipated externally through the heat dissipation metal in the trench.

In one embodiment of the light-emitting device of this invention, the trench penetrates through the active layer.

In one embodiment of the light-emitting device of this invention, the trench is an annular trench, such that the heat dissipation metal covering the annular trench surrounds the current confinement region and the active layer.

In one embodiment of the light-emitting device of this invention, the heat dissipation metal is selected from the group consisting of either a gold-tin (AuSn) alloy and gold (Au).

In one embodiment of the light-emitting device of this invention, the epitaxial layer further includes a groove that penetrates through the epitaxial layer, vertically dividing the epitaxial layer into a first region and a second region separated from each other.

In one embodiment of the light-emitting device of this invention, the trench is disposed in the first region of the epitaxial layer, and the second region of the epitaxial layer has a vertical through-hole.

In one embodiment of the light-emitting device of this invention, the light-emitting device further includes a first metal bonding pad and a second metal bonding pad, wherein the first metal bonding pad is disposed in the second region and extends vertically along the vertical through-hole to be electrically connected to the first electrode, and the second metal bonding pad is disposed in the first region and electrically connected to the second electrode.

To achieve the above objective, this invention provides a manufacturing method for a light-emitting device, comprising the following steps: providing an epitaxial layer having an active layer; providing a first electrode disposed on the epitaxial layer, the first electrode having an emission aperture; providing a trench disposed on a side of the epitaxial layer opposite to the emission aperture; performing wet oxidation on the trench to form a current confinement region on the active layer; providing a second electrode covering a surface of the trench; and providing a heat dissipation metal covering the trench. When a current flows through the first electrode and the current confinement region into the active layer, the active layer excites a light beam to pass through the current confinement region and the emission aperture to exit the epitaxial layer, and the heat generated by the active layer in the current confinement region is dissipated externally through the heat dissipation metal in the trench.

In one embodiment of the manufacturing method for the light-emitting device of this invention, the step of providing a trench is to provide an annular trench that penetrates through the active layer, such that the heat dissipation metal covers the annular trench to surround the current confinement region and the active layer.

In one embodiment of the manufacturing method for the light-emitting device of this invention, the step of performing wet oxidation on the annular trench is to form a current barrier layer on the active layer, wherein the current barrier layer has an oxidation aperture serving as the current confinement region.

In one embodiment of the manufacturing method for the light-emitting device of this invention, the oxidation aperture has a diameter of 5 to 20 micrometers (µm).

In one embodiment of the manufacturing method for the light-emitting device of this invention, the step of providing a heat dissipation metal comprises providing the heat dissipation metal selected from the group consisting of a gold-tin (AuSn) alloy and gold (Au).

In one embodiment of the manufacturing method for the light-emitting device of this invention, the method further includes a step of providing a groove that penetrates through the epitaxial layer to vertically divide the epitaxial layer into a first region and a second region separated from each other, the second region having a vertical through-hole.

In one embodiment of the manufacturing method for the light-emitting device of this invention, the method further includes a step of providing a first metal bonding pad and a second metal bonding pad, wherein the first metal bonding pad is disposed in the second region and extends vertically along the vertical through-hole to be electrically connected to the first electrode, and the second metal bonding pad is disposed in the first region and electrically connected to the second electrode.

After referring to the drawings and the embodiments as described in the following, those the ordinary skilled in this art can understand other objectives of the present invention, as well as the technical means and embodiments of the present invention.

### BRIEF DESCRIPTION OF THE DRAWINGS

FIG. 1 is a cross-sectional schematic diagram of a light-emitting device in one embodiment of this invention;

FIG. 2 is a schematic diagram illustrating the heat dissipation pathway and a partial enlarged view of the three-dimensional heat dissipation structure of a light-emitting device in one embodiment of this invention;

FIGS. 3-16 are schematic diagrams illustrating the manufacturing method of a light-emitting device in one embodiment of this invention;

FIG. 17 is a schematic diagram illustrating the packaging application of a light-emitting device in one embodiment of this invention;

FIG. 18 is a schematic diagram illustrating the packaging application of a light-emitting device in another embodiment of this invention;

FIG. 19 is a schematic diagram illustrating the packaging application of a light-emitting device in yet another embodiment of this invention; and

FIG. 20 is a flowchart illustrating the process steps of a light-emitting device in one embodiment of this invention.

### DETAILED DESCRIPTION OF THE PREFERRED EMBODIMENT

In the following description, the present invention will be explained with reference to various embodiments thereof. These embodiments of the present invention are not intended to limit the present invention to any specific environment, application or particular method for implementations described in these embodiments. Therefore, the description of these embodiments is for illustrative purposes only and is not intended to limit the present invention. It shall be appreciated that, in the following embodiments and the attached drawings, a part of elements not directly related to the present invention may be omitted from the illustration, and dimensional proportions among individual elements and the numbers of each element in the accompanying drawings are provided only for ease of understanding but not to limit the present invention.

This invention relates to a light-emitting device, particularly a VCSEL device, and a manufacturing method thereof. The invention provides a three-dimensional heat dissipation pathway to overcome the limitations of the conventional point heat source cosine function heat dissipation model in VCSEL devices, shorten the heat dissipation path, and enhance the heat dissipation efficiency and reliability of the VCSEL device, as detailed below.

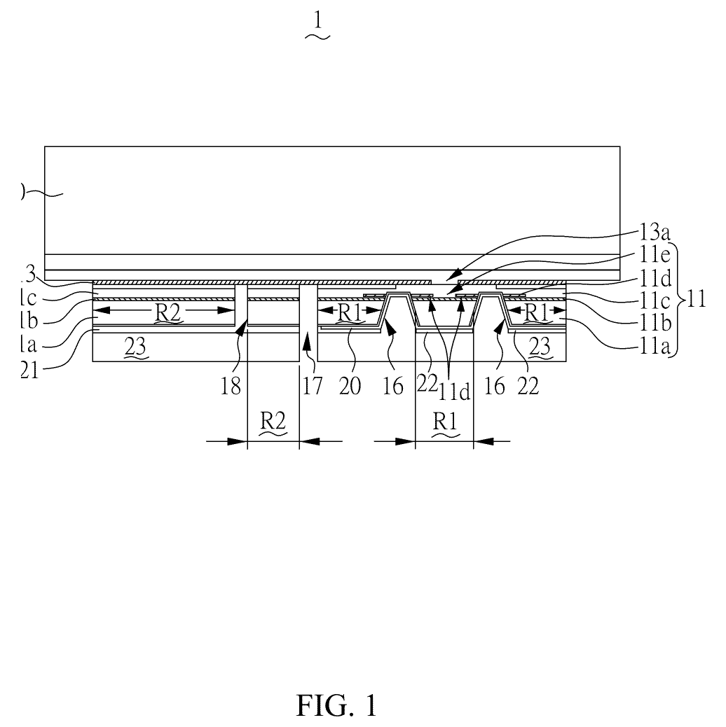

Referring to FIG. 1, a cross-sectional schematic diagram of a light-emitting device 1 in one embodiment of this invention is shown, featuring a flip-chip structure, i.e., the light-emitting device 1 is a Vertical Cavity Surface Emitting Laser (VCSEL) flip-chip. It should be noted that the flip-chip configuration is only one embodiment of this invention, and the invention can also be applied to other laser chips with point heat sources, such as vertical laser chips. As shown in FIG. 1, the light-emitting device 1 of this invention includes a substrate 10, an epitaxial layer 11, a first electrode 13, a second electrode 20, and a heat dissipation metal 23. The substrate 10 may be a sapphire (Al₂O₃) substrate, but is not limited thereto. Depending on different applications, any transparent substrate with a transmittance exceeding 90% may be used.

The epitaxial layer 11 is formed by alternately stacking gallium arsenide (GaAs), aluminum gallium arsenide (AlₓGa₁₋ₓAs), and aluminum arsenide (AlAs), with the bandgap of the epitaxial layer 11 ranging from 1.3 to 2.5 eV. In a VCSEL device, the epitaxial layer 11 includes an N-type epitaxial layer 11a, an active layer 11b, and a P-type epitaxial layer 11c, wherein the active layer 11b is a multiple quantum well structure disposed on the N-type epitaxial layer 11a, and the P-type epitaxial layer 11c is disposed on the active layer 11b. The N-type epitaxial layer 11a and the P-type epitaxial layer 11c may each be a reflector stack, such as a Distributed Bragg Reflector (DBR).

Furthermore, as shown in FIG. 1, the epitaxial layer 11 includes two current barrier layers 11d disposed in the P-type epitaxial layer 11c slightly above the active layer 11b, laterally separated by a distance to form an oxidation aperture (OA) 11e. Each current barrier layer 11d is an insulating layer formed by wet oxidation or ion implantation. The oxidation aperture 11e formed by the current barrier layers 11d has a radius ranging from 5 to 20 micrometers (µm) and serves as both a current confinement region and an optical confinement region, enabling the VCSEL device to effectively concentrate current through the oxidation aperture 11e during operation, reducing lateral current diffusion, confining light to propagate in the central region, optimizing optical distribution, and thereby improving beam quality and light emission efficiency.

Continuing to refer to FIG. 1, the epitaxial layer 11 of the light-emitting device 1 further includes a groove 17 that vertically divides the epitaxial layer 11 into a first region R1 and a second region R2, allowing the first region R1 and the second region R2 to be separated from each other. In actual manufacturing processes, the groove 17 may be formed by a wet etching process or a dry etching process. The groove 17 may remain unfilled or be filled with an elastic material, provided it can withstand stress to prevent cracking of the epitaxial layer.

The first electrode 13 is disposed on the upper surface of the P-type epitaxial layer 11c of the epitaxial layer 11 and is electrically connected to the P-type epitaxial layer 11c in the first region R1 through appropriate circuit arrangements. Specifically, the first electrode 13 includes an emission aperture 13a in the first region R1. The emission aperture 13a has a radius of approximately 5 to 10 micrometers (µm), preferably 8 micrometers (µm), and is vertically aligned with the oxidation aperture 11e of the current confinement region in the first region R1, allowing light generated by the active layer 11b to radiate vertically outward through the oxidation aperture 11e and the emission aperture 13a. The first electrode 13 is made of a metal material selected from the group consisting of silver (Ag), titanium (Ti), platinum (Pt), germanium-gold (GeAu), gold (Au), and combinations thereof. Additionally, the second electrode 20 is disposed on the surface of the N-type epitaxial layer 11a in the first region R1 of the epitaxial layer 11 and is electrically connected thereto. The second electrode 20 may be made of the same metal material as the first electrode 13, and further details are omitted here.

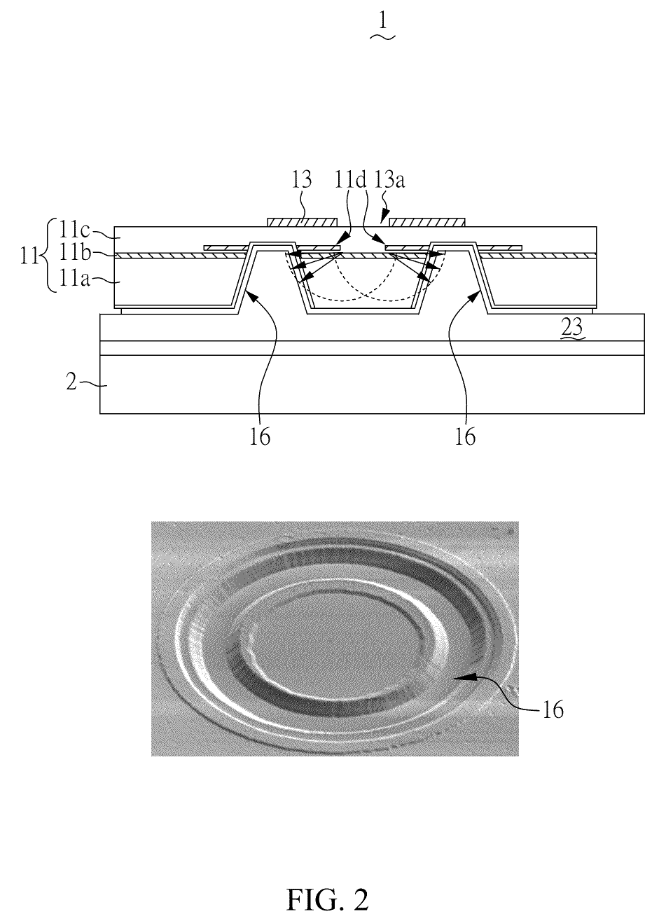

Since the gallium arsenide (GaAs)-based surface-emitting laser device primarily uses epitaxial materials such as aluminum arsenide (AlAs), aluminum gallium arsenide (AlₓGa₁₋ₓAs), and gallium arsenide (GaAs), which have poor thermal conductivity, and the heat diffusion path formed near the PN junction at the oxidation aperture 11e between the two current barrier layers 11d is confined to a small, point-like region, it is critical to address the poor heat dissipation issue of VCSEL devices. In view of this, referring to FIGS. 1 and 2 together, this invention specifically provides a trench 16 disposed on the side of the epitaxial layer 11 opposite to the emission aperture 13a, filled with a heat dissipation metal 23, which can further be physically connected to a heat sink 2. Thus, when an external current is introduced into the first electrode 13 and flows through the current confinement region into the active layer 11b, the active layer 11b excites a light beam to radiate outward through the current confinement region and the emission aperture 13a, exiting the epitaxial layer 11. Meanwhile, the heat generated by the active layer 11b in the current confinement region is dissipated externally through the heat dissipation metal 23 in the trench 16.

As shown in FIG. 2, compared to the heat dissipation pathway of the aforementioned cosine function heat dissipation model, the heat dissipation metal 23 in the trench 16 is closer to the active layer 11b generating heat in the current confinement region, enabling effective heat dissipation. For clarity, FIG. 2 shows an enlarged view of the oxidation aperture 11e, clearly illustrating that the heat dissipation pathway between the active layer 11b near the oxidation aperture 11e and the heat dissipation metal 23 is substantially shortened, as indicated by the dashed heat dissipation range covering the heat dissipation metal 23 in the trench 16. Preferably, the trench 16 further penetrates through the active layer 11b, allowing the heat dissipation metal 23 in the trench 16 to be even closer to the heat source in the current confinement region. In a preferred embodiment, the trench 16 is an annular trench, as shown in the partial enlarged view on the right side of FIG. 2, where the annular structure of the trench fully surrounds the current confinement region and the active layer in a three-dimensional manner, enabling the heat dissipation metal covering the annular trench to dissipate heat more efficiently, addressing the issue of poor heat dissipation efficiency in conventional VCSEL devices with point heat sources.

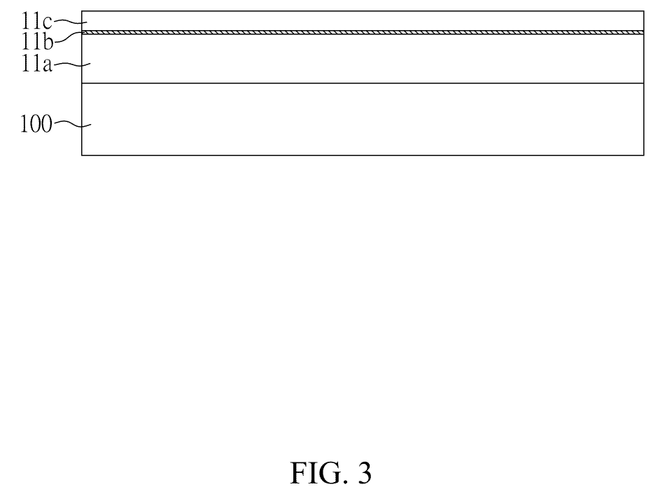

Referring to FIGS. 3-16, the manufacturing method of the VCSEL light-emitting device of this invention is illustrated. As shown in FIG. 3, the epitaxial layer 11, comprising an N-type epitaxial layer 11a, an active layer 11b, and a P-type epitaxial layer 11c, is formed on an epitaxial growth substrate 100 using Group III-V or Group II-VI semiconductor materials through Metal-organic Chemical Vapor Deposition (MOCVD) or Molecular Beam Epitaxy (MBE). In this embodiment, the epitaxial growth substrate 100 may be, for example, but not limited to, an N-type gallium arsenide (GaAs) substrate. Additionally, the epitaxial layer 11 includes a high-aluminum layer (not shown) disposed near the location above the active layer 11b, which may be an aluminum arsenide (AlAs) layer or an aluminum gallium arsenide (AlₓGa₁₋ₓAs, x ≥ 0.98) layer, oxidized in a subsequent process to form a current barrier layer.

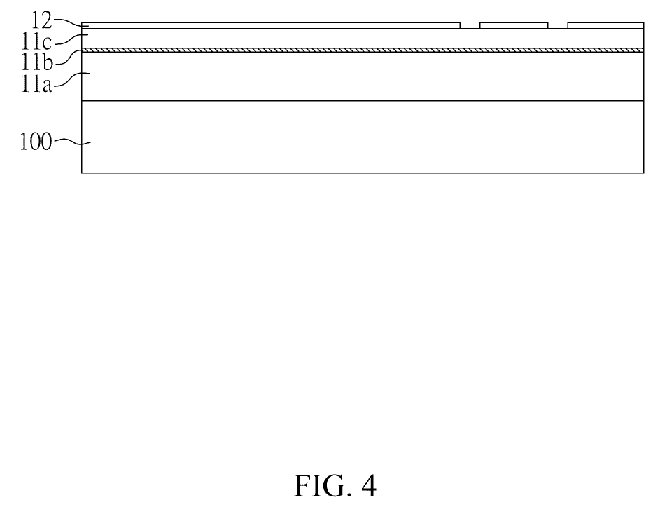

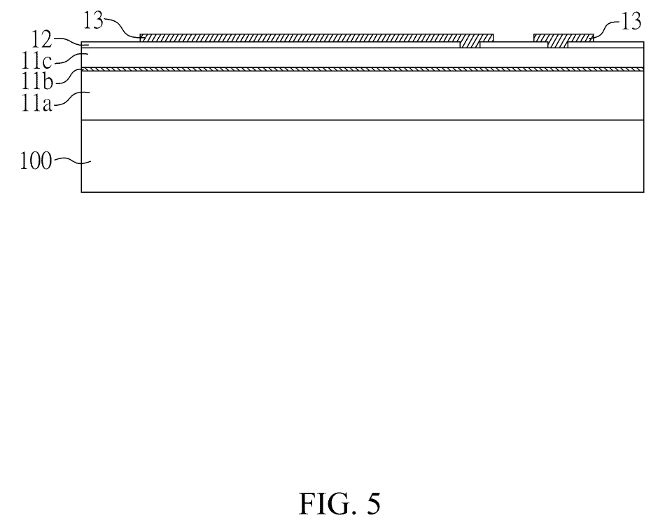

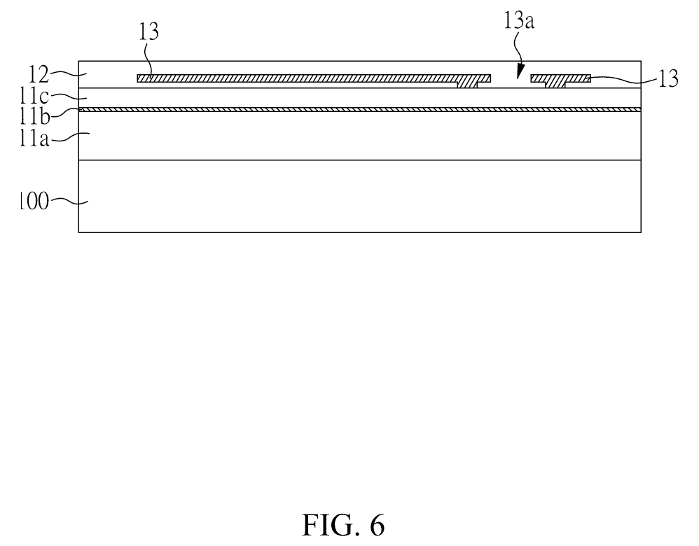

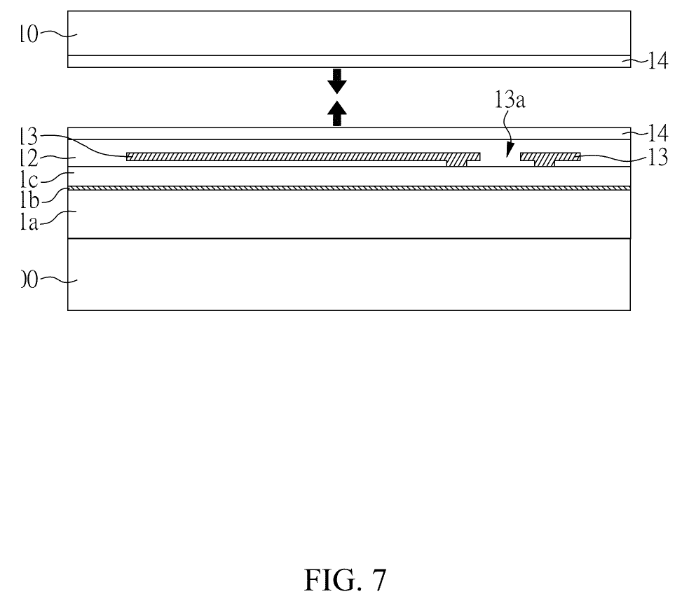

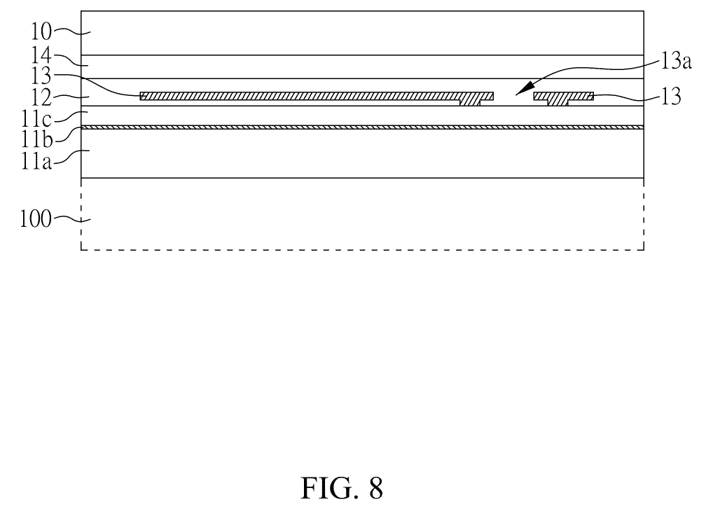

FIG. 4 shows the formation of an insulating layer 12 on the surface of the epitaxial layer 11, followed by a patterning process on the insulating layer 12 to etch patterns for forming ohmic contact with the P-type epitaxial layer 11c. Next, as shown in FIG. 5, a P-type metal evaporation process is performed to form the first electrode 13 on the insulating layer 12, establishing ohmic contact and electrical connection with the P-type epitaxial layer 11c. The first electrode 13 is made of a metal material selected from the group consisting of silver (Ag), titanium (Ti), platinum (Pt), germanium-gold (GeAu), gold (Au), and combinations thereof. Subsequently, the first electrode 13 is patterned and etched to form the emission aperture 13a, as shown in FIG. 6. Additionally, referring to FIG. 7, a benzocyclobutene (BCB) layer 14 is coated on the insulating layer 12, and wafer bonding is performed with a BCB layer 14 on one side of another substrate 10, which may be a transparent substrate such as glass or sapphire. After wafer bonding, the epitaxial growth substrate 100 is removed, as shown in FIG. 8.

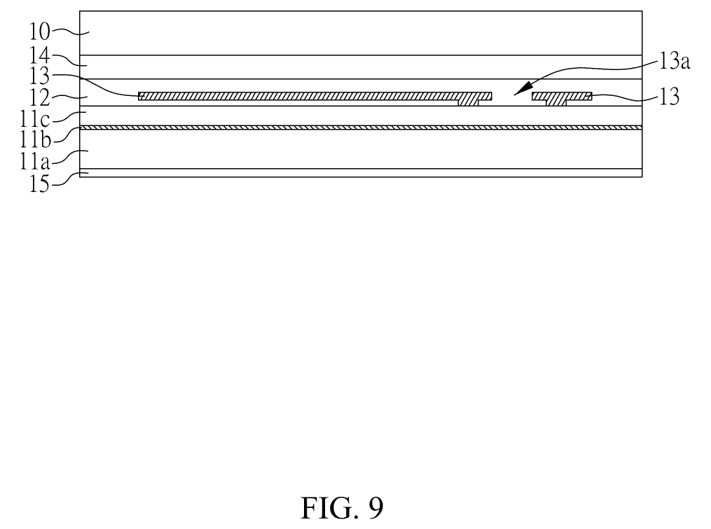

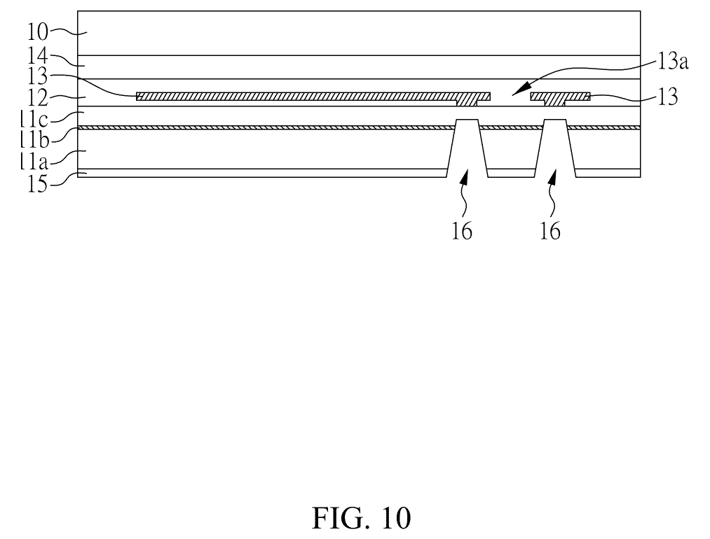

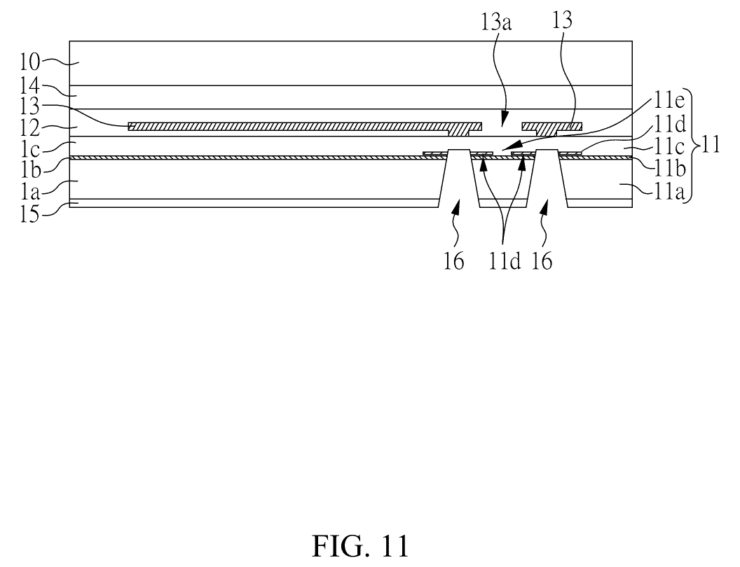

Referring to FIG. 9, an insulating layer 15 is formed on the side of the epitaxial layer 11. Next, the epitaxial layer 11 is patterned and etched to form a trench 16 on the side of the epitaxial layer 11 opposite to the emission aperture 13a. As described earlier, in a preferred embodiment, the trench 16 is a three-dimensional annular trench penetrating through the active layer 11b to effectively shorten the heat dissipation path of the active layer and improve heat dissipation efficiency, as shown in FIG. 10. Furthermore, the invention utilizes the feature of the trench 16 penetrating through the active layer 11b for performing wet oxidation on the high-aluminum layer in the epitaxial layer at the sidewall of the annular trench, precisely forming an oxide layer 0.5 to 1 micrometer (µm) above the active layer 11b inside the epitaxial layer from the trench sidewall, serving as the current barrier layer 11d for the current confinement region, with the current barrier layer 11d surrounding the oxidation aperture 11e to confine current and light emission, as shown in FIG. 11.

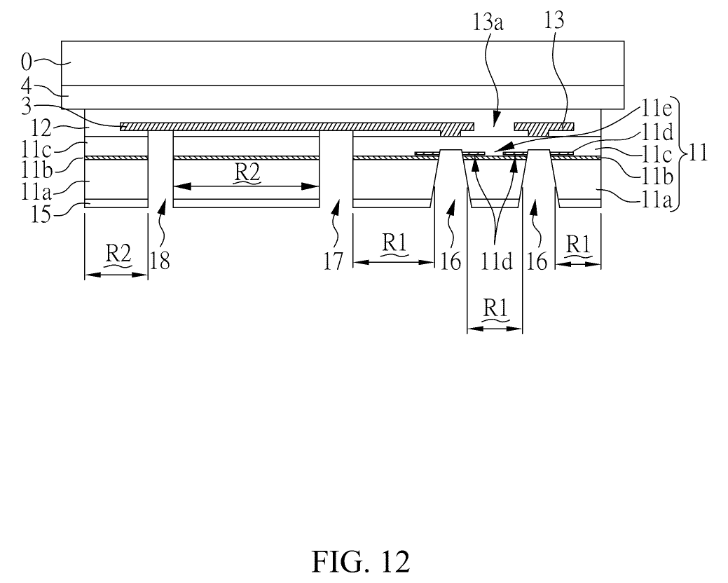

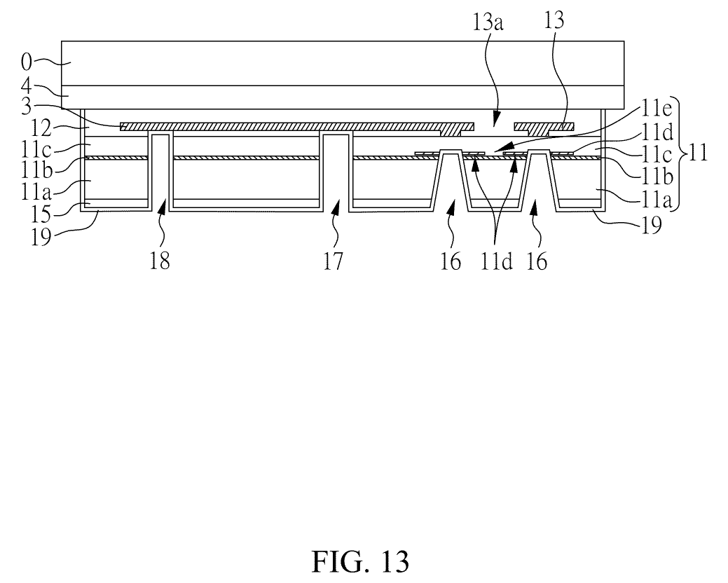

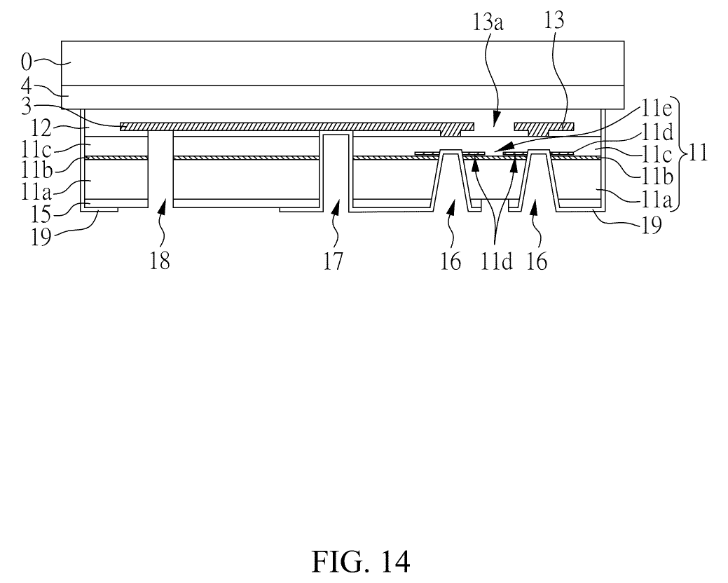

Next, referring to FIG. 12, the epitaxial layer 11 is patterned and etched to form a groove 17 and a vertical through-hole 18, and a mesa etching process is performed on the entire epitaxial layer 11. The groove 17 vertically divides the epitaxial layer 11 into a first region R1 and a second region R2, separating the epitaxial layer 11 into two distinct parts. The vertical through-hole 18 is disposed in the second region R2, penetrating through the epitaxial layer 11 and the insulating layer 12 in the second region R2 to expose a portion of the first electrode 13, serving as part of the electrode circuit formed subsequently. In actual manufacturing processes, the groove 17 and the vertical through-hole 18 may be formed by a wet etching process or a dry etching process. The groove 17 may remain unfilled or be filled with an elastic material, provided it can withstand stress to prevent cracking of the epitaxial layer. Next, referring to FIG. 13, an insulating layer 19 is formed to completely cover the trench 16, the groove 17, the vertical through-hole 18, and other exposed surfaces. Subsequently, a photolithography process is performed to expose the predetermined regions for the second electrode and the two electrode bonding pads of the light-emitting device 1, as shown in FIG. 14.

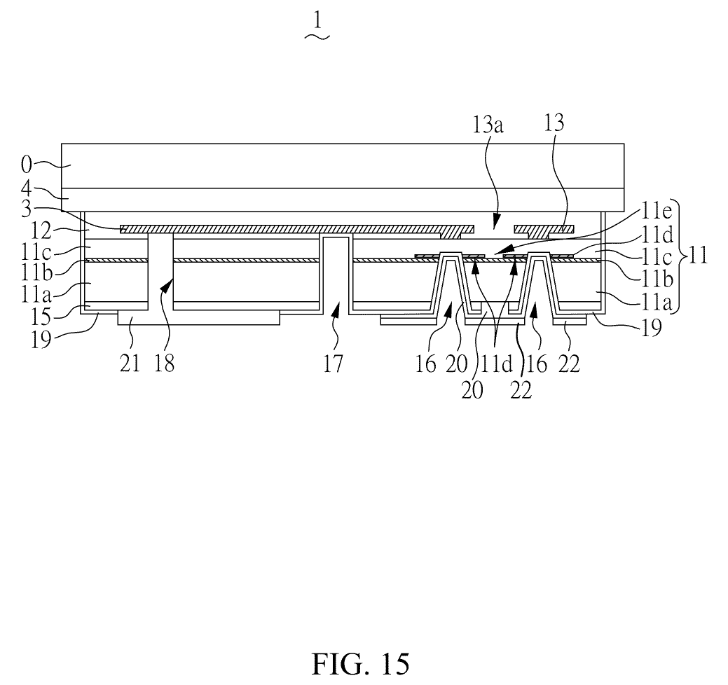

Referring to FIG. 15, a metal evaporation process is performed to first form a second electrode 20 covering the surface of the trench 16 in the first region and the exposed surface of the N-type epitaxial layer 11a corresponding to the current confinement region above, completing the circuit loop of the VCSEL device in conjunction with the first electrode 13. Then, the metal evaporation process continues to form a first metal bonding pad 21 and a second metal bonding pad 22, each electrically connected to the first electrode 13 and the second electrode 20, respectively. The first metal bonding pad 21 serves as the P-side pad of the light-emitting device 1, acting as the positive electrode of the flip-chip light-emitting device, filling the vertical through-hole 18 and disposed below the N-type epitaxial layer 11a in the second region R2 of the epitaxial layer 11, extending vertically to be electrically connected to the first electrode 13. The second metal bonding pad 22 serves as the N-side pad of the light-emitting device 1, acting as the negative electrode of the flip-chip light-emitting device, disposed in the first region R1 of the epitaxial layer 11 and electrically connected to the second electrode 20. The first metal bonding pad 21 and the second metal bonding pad 22 are made of the same material, selected from the group consisting of silver (Ag), titanium (Ti), platinum (Pt), germanium-gold (GeAu), gold (Au), and combinations thereof.

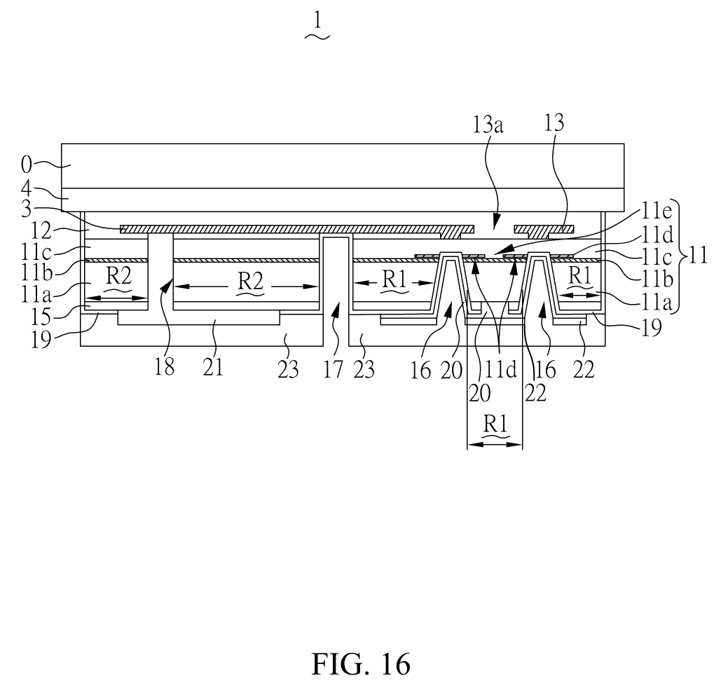

Referring to FIG. 16, before applying the light-emitting device 1 of this invention to a packaging structure, a heat dissipation metal 23 is further filled to cover the trench 16 in the first region R1 and below the second metal bonding pad 22, and also filled to cover below the first metal bonding pad 21 in the second region R2, enabling the heat dissipation metal 23 to form physical ohmic contact with the heat sink 2 of the chip packaging structure, as shown in FIG. 2, to rapidly transfer heat generated inside the chip to the outside. Specifically, if a eutectic bonding process is used in subsequent applications, a gold-tin (AuSn) alloy with a gold-to-tin ratio of 8:2 is used as the heat dissipation metal material. Alternatively, if a nano-sintered silver process is used in backend applications, pure gold is preferably used as the heat dissipation metal material.

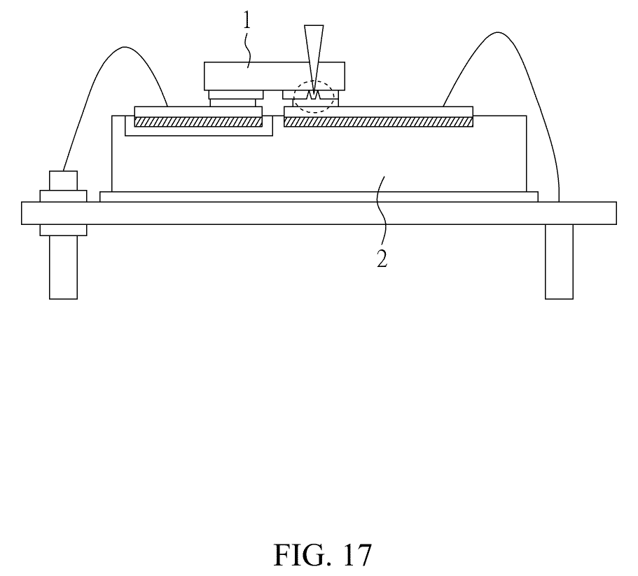

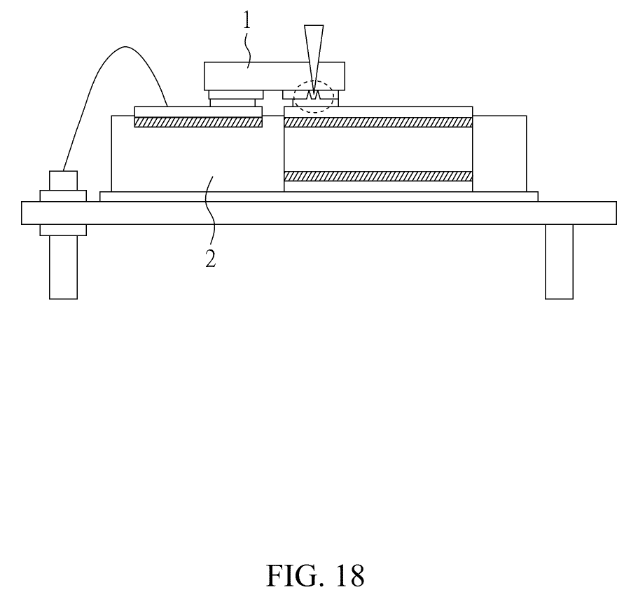

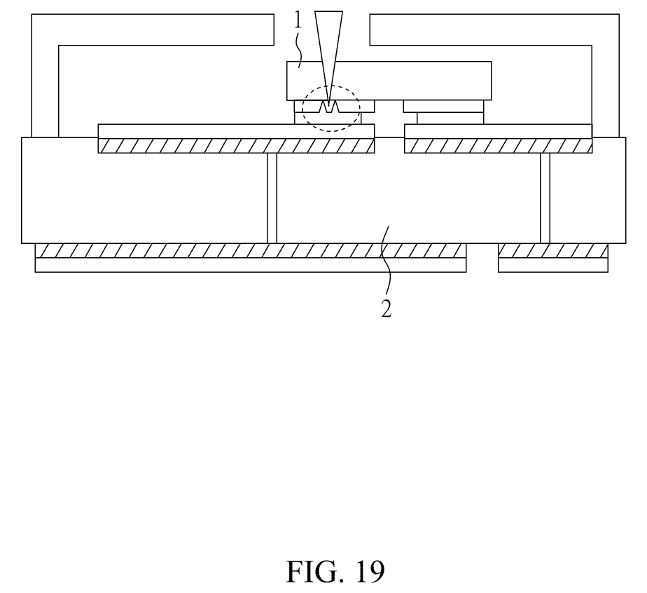

Referring to FIGS. 17 -19, examples of specific packaging configurations applying the light-emitting device 1 of this invention are shown. FIG. 17 illustrates a schematic diagram of the light-emitting device 1 applied to a TO-CAN (Transistor Outline CAN) laser mount packaging structure, paired with a heat dissipation substrate with copper bumps as the heat sink 2, allowing the three-dimensional trench heat dissipation structure, as indicated by the dashed circle in FIG. 17, to rapidly transfer high heat generated in the current confinement region of the flip-chip light-emitting device to the outside, overcoming the limitations of the point heat source heat dissipation model. Next, FIG. 18 illustrates a schematic diagram of the light-emitting device 1 applied to another packaging structure with a copper carrier, where the heat sink 2, as shown in FIG. 18, uses a copper carrier paired with Resin Coated Copper (RCC) material or a Bismaleimide Triazine (BT) resin substrate as the heat dissipation packaging base, also rapidly transferring high heat generated in the current confinement region, as indicated by the dashed circle in FIG. 18, to the outside. Additionally, FIG. 19 illustrates a schematic diagram of the light-emitting device 1 applied to a packaging structure with an aluminum nitride ceramic substrate as the heat sink 2, where the three-dimensional trench heat dissipation structure, as indicated by the dashed circle in FIG. 19, similarly enables rapid external heat dissipation, overcoming the drawbacks of poor heat dissipation in conventional point heat source models.

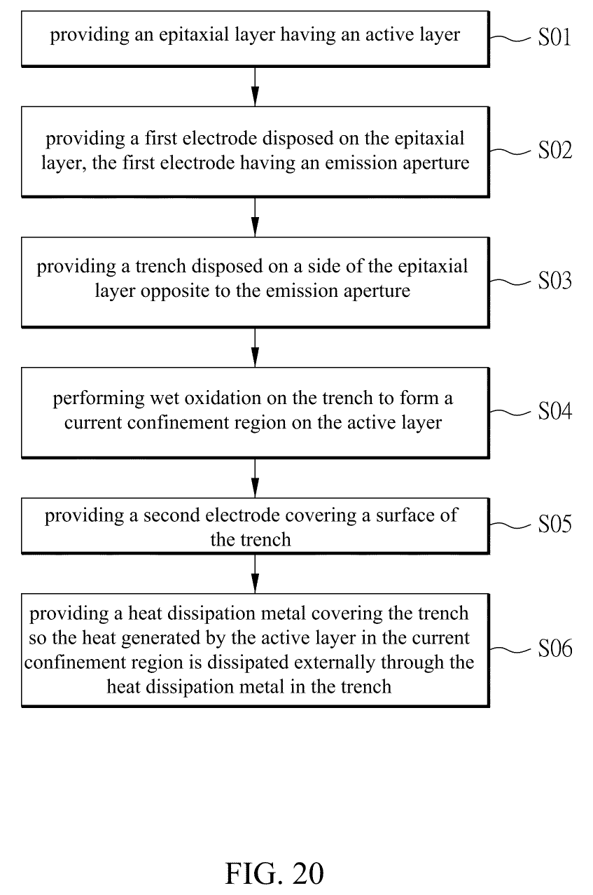

Referring to FIG. 20, a flowchart of the manufacturing steps for the VCSEL light-emitting device of this invention is shown. First, in step S01, an epitaxial layer is provided, the epitaxial layer including an active layer. In step S02, a first electrode is provided, disposed on the epitaxial layer, the first electrode having an emission aperture. In step S03, a trench is provided, disposed on a side of the epitaxial layer opposite to the emission aperture. Next, in step S04, wet oxidation is performed on the trench to form a current confinement region on the active layer. In step S05, a second electrode is provided, covering a surface of the trench. Finally, in step S06, a heat dissipation metal is provided, covering the trench, wherein when a current flows through the first electrode and the current confinement region into the active layer, the active layer excites a light beam to pass through the current confinement region and the emission aperture to exit the epitaxial layer, and the heat generated by the active layer in the current confinement region is dissipated externally through the heat dissipation metal in the trench. Detailed descriptions of related components can refer to the above content and are not repeated here.

The above embodiments are provided to illustrate the implementations of the present invention and to explain its technical features, and are not intended to limit the scope of the present invention. Any modifications or equivalent arrangements that can be easily accomplished by those skilled in the art fall within the scope of the present invention, and the scope of the present invention should be defined by the claims.

What is claimed is:

1. A light-emitting device, comprising:
an epitaxial layer having a current confinement region and an active layer;
a first electrode disposed on the epitaxial layer, having an emission aperture, wherein when a current flows through the first electrode and the current confinement region into the active layer, the active layer excites a light beam to pass through the current confinement region and the emission aperture to exit the epitaxial layer;
a trench disposed on a side of the epitaxial layer opposite to the emission aperture;
a second electrode covering a surface of the trench; and
a heat dissipation metal covering the trench, enabling heat generated by the active layer in the current confinement region to be dissipated externally through the heat dissipation metal in the trench.

2. The light-emitting device of claim 1, wherein the trench penetrates through the active layer.

3. The light-emitting device of claim 2, wherein the trench is an annular trench, such that the heat dissipation metal covering the annular trench surrounds the current confinement region and the active layer.

4. The light-emitting device of claim 1, wherein the heat dissipation metal is selected from the group consisting of a gold-tin (AuSn) alloy and gold (Au).

5. The light-emitting device of claim 1, wherein the epitaxial layer further includes a groove that penetrates through the epitaxial layer, vertically dividing the epitaxial layer into a first region and a second region separated from each other.

6. The light-emitting device of claim 5, wherein the trench is disposed in the first region of the epitaxial layer, and the second region of the epitaxial layer has a vertical through-hole.

7. The light-emitting device of claim 6, further comprising a first metal bonding pad and a second metal bonding pad, wherein the first metal bonding pad is disposed in the second region and extends vertically along the vertical through-hole to be electrically connected to the first electrode, and the second metal bonding pad is disposed in the first region and electrically connected to the second electrode.

8. A manufacturing method for a light-emitting diode, comprising:
providing an epitaxial layer having an active layer;
providing a first electrode disposed on the epitaxial layer, the first electrode having an emission aperture;
providing a trench disposed on a side of the epitaxial layer opposite to the emission aperture;
performing wet oxidation on the trench to form a current confinement region on the active layer;
providing a second electrode covering a surface of the trench; and
providing a heat dissipation metal covering the trench,
wherein when a current flows through the first electrode and the current confinement region into the active layer, the active layer excites a light beam to pass through the current confinement region and the emission aperture to exit the epitaxial layer, and the heat generated by the active layer in the current confinement region is dissipated externally through the heat dissipation metal in the trench.

9. The manufacturing method for a light-emitting device of claim 8, wherein the step of providing a trench is to provide an annular trench that penetrates through the active layer, such that the heat dissipation metal covers the annular trench to surround the current confinement region and the active layer.

10. The manufacturing method for a light-emitting device of claim 9, wherein the step of performing wet oxidation on the annular trench is to form a current barrier layer on the active layer, wherein the current barrier layer has an oxidation aperture serving as the current confinement region.

11. The manufacturing method for a light-emitting device of claim 10, wherein the oxidation aperture has a diameter of 5 to 20 micrometers (µm).

12. The manufacturing method for a light-emitting device of claim 8, wherein the step of providing a heat dissipation metal comprises providing the heat dissipation metal selected from the group consisting of a gold-tin (AuSn) alloy and gold (Au).

13. The manufacturing method for a light-emitting device of claim 8, further comprising a step of providing a groove that penetrates through the epitaxial layer to vertically divide the epitaxial layer into a first region and a second region separated from each other, the second region having a vertical through-hole.

14. The manufacturing method for a light-emitting device of claim 13, further comprising a step of providing a first metal bonding pad and a second metal bonding pad, wherein the first metal bonding pad is disposed in the second region and extends vertically along the vertical through-hole to be electrically connected to the first electrode, and the second metal bonding pad is disposed in the first region and electrically connected to the second electrode.
